(19) United States
(12) Patent Application Publication
(10) Pub. No.: US 2022/0038047 A1
(43) Pub. Date: Feb. 3, 2022

(54) Inflatable non-imaging non-tracking solar concentrator based concentrating photovoltaic system powered airship

(71) Applicant: Yonghua Wang, Klamath Falls, OR (US)

(72) Inventor: Yonghua Wang, Klamath Falls, OR (US)

(21) Appl. No.: 16/873,878

(22) Filed: Aug. 3, 2020

(51) Int. Cl. H02S 40/22; B64B 1/14

(52) U.S. Cl. CPC H02S 40/22; H02S 10/40; B64B 1/14

(57) ABSTRACT

An inflatable non-imaging non-tracking solar concentrator based Concentrating Photovoltaic (CPV) system powered airship consists of a conventional airship with an upper transparent cover and an array of inflatable non-imaging non-tracking concentrator based CPV modules. Where in, the inflatable non-imaging non-tracking solar concentrators are inflated with helium or hydrogen and fused into the structure of the airship to generate lifting force and concentrate sunlight to supply power simultaneously. The introduction of the CPV system into the airship dramatically reduces the cost and significantly raises conversion efficiency of the photovoltaic system without adding any extra weight to the airship. The expansion of the airship will both increase the buoyant force and power supply.

### TECHNICAL FIELD

The present disclosure relates generally to airships, more specifically, to inflatable non-imaging non-tracking solar concentrator based Concentrating Photovoltaic (CPV) system powered airships.

### BACKGROUND

Currently over 80% freights transportation in international trade over the world is carried out through ocean shipping. Apparently this is due to the remarkable shipping capacity and desirable low cost of ocean shipping. Contrast to air transportation, the ships in ocean floating on sea water rely on the buoyant force of water and need very limited driving force to navigate, while the air planes completely rely on the thrusts of engines to fly. Obviously the buoyant force no matter from water or air greatly facilitates the ships or aircrafts, in terms of the capacity and cost of transportation. Therefore, even though air plane dominates the air transportation market over airship due to its speed and convenience, airship still posses its great potential in transporting cargos over long distance. Particularly, two-third of the world land is not reachable through road and planes. Airship is able to vertically take off and land without airports. Contrast to water, air has much lower density and consequently is able to generate much lower buoyant force in the same volume. This circumstance results in a fact that extraordinarily large volume of airship is necessary to generate enough buoyant force to lift cargos. This seems to appear a drawback of airship; however, large volume means large surface area which provides a possibility to be turned into a large area solar collection field. In fact, solar powered airship presents many unprecedented opportunities to remote passenger transportation, disaster rescue transportation, military transportation, and so on. Solar powered airship is able to travel long distance without consuming fuel, take off and land without airports, and reach out any areas with complicated situations. Moreover, the solar powered airship has the potential to be turned into a floating platform to generate power during its voyage in transporting goods.

In spite of the innate advantage of solar powered airship, the wide-spread adoption of solar powered airships has never happened. The issue that hindered the wide-spread adoption of solar powered airships stems from the current approach in constructing the solar powered airship. The general configuration of the current solar powered airship consists of a conventional airship and a thin film photovoltaic system where the thin film photovoltaic system is simply coupled onto the conventional airship by covering the thin film panels onto the upper surface of the conventional airship.

U.S. Pat. No. 8,894,002 B2 to Goelet disclosed a solar powered airship. Goelet's disclosure mainly consists of a conventional airship with a propulsion system, a photovoltaic system, and a battery storage system, where the photovoltaic system plus the storage system supply power to the propulsion assembly coupled to the airship. In the configuration of Goelet's disclosure, the photovoltaic system which is mainly a assembly of solar panels is simply coupled to the airship by covering the upper surface of the airship with the solar panels.

As most designs of solar powered airships, Goelet's disclosure deploys flat plate photovoltaic panels (most likely thin film solar cell panels) for solar energy collection. Although, it is easy to integrate the solar panels onto the airship, the solar panels have relatively low conversion efficiency and high cost, and furthermore, add significant amount of weight to the airship. Concentrating Photovoltaic (CPV) System has a great potential to dramatically reduce the cost and substantially raise the efficiency of the solar energy collection and conversion system, and simultaneously significantly reduce the weight of the solar system. While, it is not easy to integrate a CPV system into an airship system. In addition, Goelet's disclosure gas bags, which have no any benefit to the energy collection and conversion, are involved into the hull of the airship system to generate lifting force. Vice verse, the solar panels for energy collection and conversion have no contribution to lifting force generation.

In terms of interception of sunlight, the solar panels simply coupled on the conventional airship may not always at the position collecting the incident sunlight in a maximized manner, due to the motion of the airship.

U.S. Pub. No.: US 2002/0134884 A1 applied by Perry disclosed an Autonomous Stratospheric Airship. In Perry's disclosure, apart from an automatic control system for autonomous driving, a solar tracking system is incorporated into the airship system for maximizing solar collection. Although, solar tracking system effectively maximizes the solar collection, the introduction of solar tracking system significantly increases the instability of the solar system due to the moving parts.

The fix mounted solar panels on the mobile airship system are not always at the positions to collect the sunlight in an optimized manner. One of the grand challenges in designing and embodying the solar system for airship is to design a stationary CPV system, which has high concentration ratio, high conversion efficiency, low cost, low self weight, and innate optimized energy harvesting position, and incorporate into the mobile airship system.

The objective of the instant invention is to provide a design paradigm of solar powered airship, which deploys CPV system to supply power to the airship; the CPV system is a stationary system, which has high concentration ratio, high conversion efficiency, low cost, low self weight, and innate optimized energy harvesting position, and is easy to be incorporated into the mobile airship system; the CPV system serving as gas bags will contribute to the lifting force generation; the gas bags involved CPV to support power supply.

### SUMMARY

The present invention is directed to a configuration of solar powered airship, in which, instead of solar panels coupled on the upper surface of conventional airship, a CPV system is fused into the structure of airship to supply power. The CPV system is the unique Inflatable Non-imaging Non-tracking Solar Concentrator (INNSC) based Concentrating Photovoltaic (CPV) system. The INNSC-CPV consists of an INNSC filled with lighter than air gases such as helium or hydrogen and a concentrating photovoltaic receiver with high conversion efficiency. The INNSC concentrates solar radiation including beam light and diffuse light with any incident angles to the receiver in a high concentration ratio. The INNSC enables the dramatic shrinkage of the photovoltaic receiver area and consequently significantly reduces the cost of the CPV system. The INNSC innately has the great potential to realize the extremely low cost. The INNSC is used to replace the conventional gas bags to generate lifting force, or other way around the gas bags are shaped into solar concentrators to support power generation.

The present invention is also directed to a method to optimize the solar collection on the mobile floating platform. The INNSC array fused into the airship structure harvests the solar energy in an optimized manner anywhere and anytime without tracking.

The present invention is also directed to a method to extend the solar collection area without adding weight to the airship and create a solar collection platform without occupying land.

Further aspects and advantages of the present invention will become apparent upon consideration of the following description thereof, reference being made of the following drawing.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 is the overview of the airship with the transparent upper cover, tailor wings, and propulsion system.

FIG. 2 is another overview of the airship with the transparent upper cover, tailor wings, and propulsion system.

FIG. 3 is the cross section view of the airship with the transparent upper cover, tailor wings, and propulsion system, and the inflatable non-imaging non-tracking solar concentrator array based CPV system.

FIG. 4 is another cross section view of the airship with the transparent upper cover and the inflatable non-imaging non-tracking solar concentrator array based CPV system; in addition, an indication of the obliquely incident sunlight concentrated by the inflatable non-imaging non-tracking solar concentrator array.

FIG. 5 is the inflatable non-imaging non-tracking solar concentrator with a Compound Parabolic Concentrator (CPC) made of reflective film, a domed upper transparent cover, and a flat bottom transparent cover.

FIG. 6 is a schematic drawing of the inflatable non-imaging non-tracking solar concentrator showing the concentration process of both beam light and diffuse light.

FIG. 7 is the inflatable non-imaging non-tracking solar concentrator with a Compound Parabolic Concentrator (CPC) made of reflective film, a domed upper transparent cover, and a flat bottom transparent cover, as well as a receiver made of a concentrating photovoltaic panel and a heat exchanger.

FIG. 8 is the inflatable non-imaging non-tracking solar concentrator with a CPC made of reflective film, a domed upper transparent cover, and a flat bottom transparent cover, and a domed divergent Fresnel lens on the top of the domed upper transparent cover.

FIG. 9 is the geometric diagram showing the refraction mechanism that changes the direction of the incident light through the domed divergent Fresnel lens during a diurnal day.

### DETAILED DESCRIPTION

Reference will now be made in detail to the present exemplary embodiments, examples of which are illustrated in the accompanying drawings. Wherever possible, the same reference numbers will be used throughout the drawings to refer to the same or like parts.

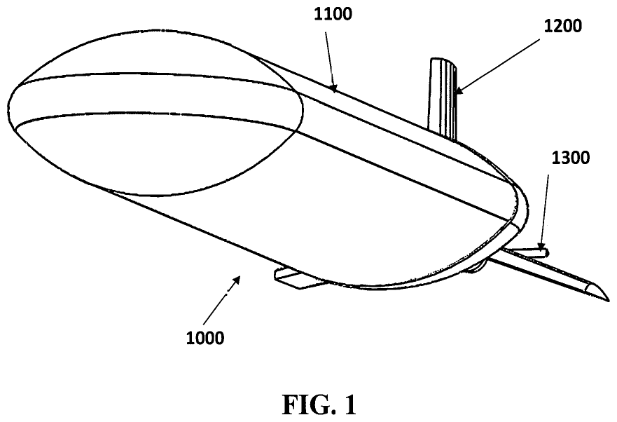

Referring to FIG. 1, instead of solar panels on the upper cover of conventional solar powered airship, the upper cover 1100 of the solar powered airship of the present invention is a transparent cover, which allows sunlight to penetrate through the cover and reach to the CPV system inside of the airship body.

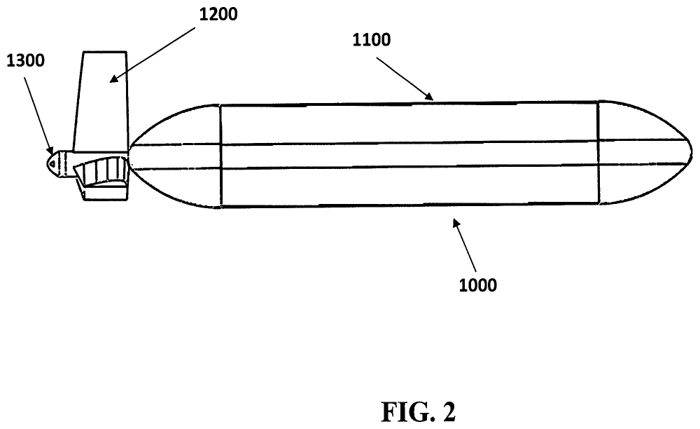

Referring to FIG. 2, the airship of present invention looks like a conventional airship with the body frame 1000, tailor wings 1200, propulsion system 1300, except that the upper cover of the body frame 1100 is transport.

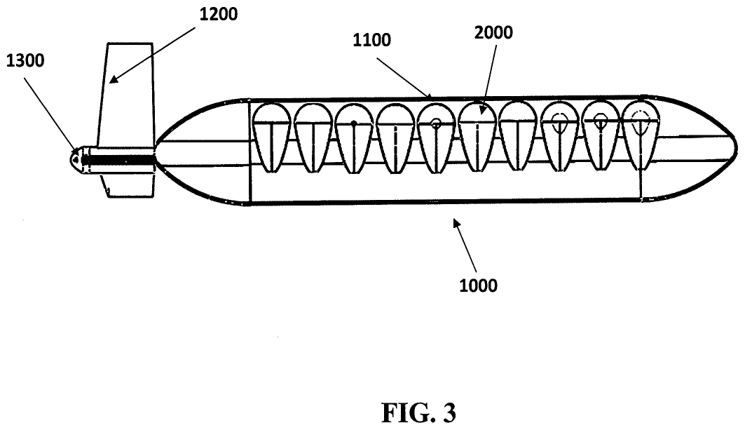

Referring to FIG. 3, airship of the present invention contains an inflatable non-imaging non-tracking solar concentrator array based CPV system 2000 inside of the airship body frame 1000, and the solar concentrators of the CPV system are filled with lighter than air gases such as helium and hydrogen to generate buoyant lifting force.

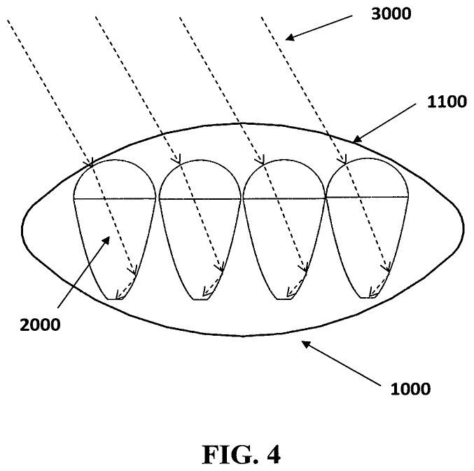

Referring to FIG. 4, the obliquely incident sunlight 3000 which penetrates through the transparent cover 1100 and reaches to the inflatable non-imaging non-tracking solar concentrator array 2000 is refracted and concentrated by the solar concentrator array.

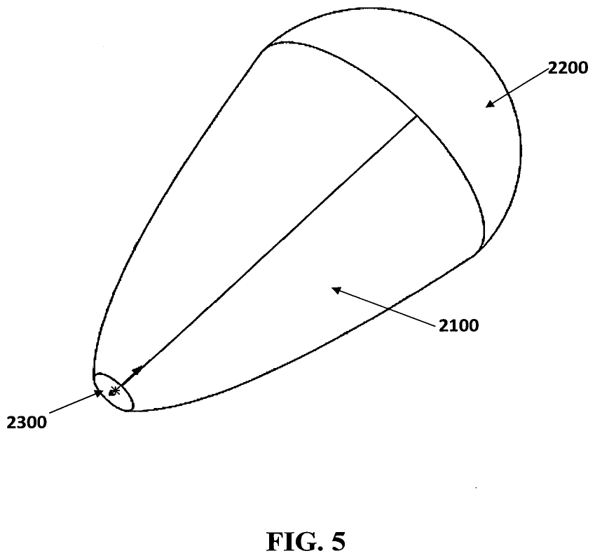

Referring to FIG. 5, the inflatable non-imaging non-tracking solar concentrator is formed by such a way that two transparent membranes and one reflective membrane are sealed together into a pre-form, then the pre-form is inflated into a balloon type CPC 2100, with its top covered with a domed transparent cover 2200 and its bottom covered with a flat transparent cover 2300.

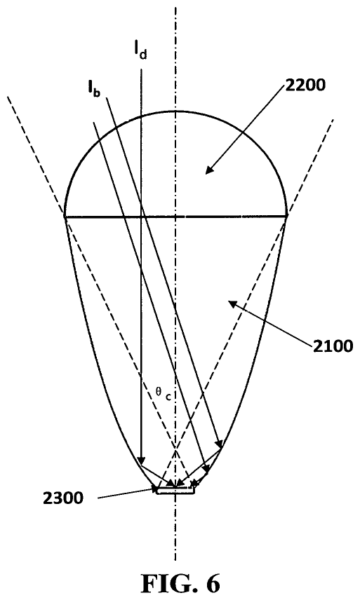

Referring to FIG. 6, the CPC is able to concentrate both the beam light I_{b} and the diffuse light I_{d}, as long as their incident angles relative to the CPC are smaller than the acceptance half-angle of the CPC.

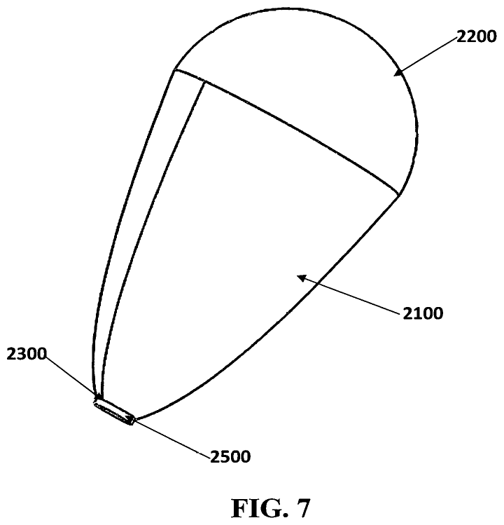

Referring to FIG. 7, a photovoltaic receiver 2500, which is a combination of a concentrating photovoltaic panel and a heater exchanger, is sealed into the inflatable non-imaging non-tracking concentrator to form a concentrating photovoltaic system.

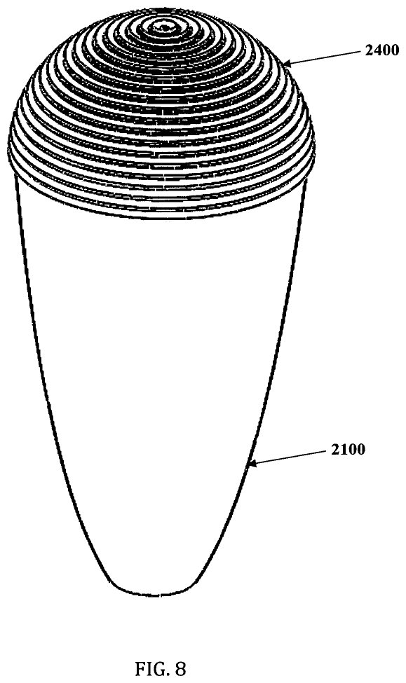

Referring to FIG. 8, in the present invention, a flexible divergent Fresnel lens 2400 is added on the top of the domed transparent cover of the inflatable CPC 2100 with small acceptance half-angle, so that the oblique incident light is refracted to fall in the small acceptance half-angle.

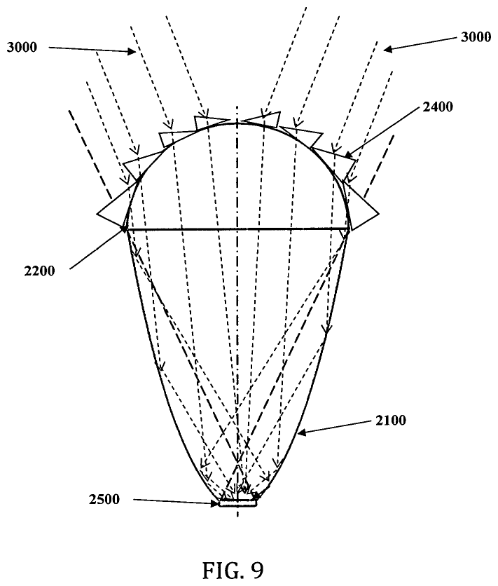

Referring to FIG. 9, the general work principle of the domed divergent Fresnel lens and CPC based non-tracking non-imaging concentrating system is elucidated. The obliquely incident light 3000 is firstly infracted by the divergent Fresnel lens 2400 to changing its incident angle relative to the CPC, and make it smaller than the half acceptance angle of the CPC, then is concentrated by the CPC non-imaging concentrator 2100.

The work principle of the non-tracking concentrator structure is elucidated as the following. As the sun moving from east to west, the sunlight is refracted to change direction by various portion of the domed divergent Fresnel lens surrounding the CPC, so that the refracted sunlight falls into the relatively small acceptance half-angle of the CPC and is concentrated by it. The addition of the domed divergent Fresnel lens to the CPC enlarges the acceptance angle of the CPC, and therefore enables the stationary concentration with high concentration ratio.

From the description above, a number of advantages of the solar powered airship become evident. A CPV system is fused into the airship structure to replace one of the components of airship the lighter than air gas containers without adding self weight, to dramatically reduce the area of solar panels of the conventional solar powered airship and consequently reduce the cost. The shrunk receiver of the CPV system enables the adoption of high efficiency photovoltaic converter without too much concern of cost. The non-imaging non-tracking mechanism of the inflatable solar concentrator ensures the optimized solar energy harvesting at anywhere any time with high concentration ratio. The expansion of the volume of the airship will both increase the lifting capability and power generation capability.

In the preceding specification, various preferred embodiments have been described with reference to the accompanying drawings. It will, however, be evident that various other modifications and changes may be made thereto, and additional embodiments may be implemented, without departing from the broader scope of the invention as set forth in the claims that follow. The specification and drawings are accordingly to be regarded in an illustrative rather than restrictive sense.

Other embodiments of the invention will be apparent to those skilled in the art from consideration of the specification and practice of the invention disclosed herein. It is intended that the specification and examples be considered as exemplary only, with the true scope and spirit of the invention being indicated by the following claims.

1. A solar powered airship comprising an airship body with a transparent upper cover and an inflatable non-imaging non-tracking solar concentrator based Concentrating PhotoVoltaic (CPV) system, the inflatable non-imaging non-tracking solar concentrator based CPV system is located inside of the body of the airship beneath the transparent cover;
Wherein the oblique incident sunlight including beam light and diffuse light penetrating through the upper transparent cover of the airship body can be concentrated and converted into electric power by the inflatable non-imaging non-tracking solar concentrator based CPV system.

2. The inflatable non-imaging non-tracking solar concentrator based CPV system of claim 1, comprises an array of inflatable non-imaging non-tracking solar concentrator based CPV modules.

3. The inflatable non-imaging non-tracking solar concentrator based CPV module of claim 2, comprises an inflatable non-imaging non-tracking solar concentrator and a concentrating receiver.

4. The inflatable non-imaging non-tracking solar concentrator of claim 3, comprises a balloon type container inflated into a Compound Parabolic Concentrator (CPC) with a domed upper transparent cover and a flat bottom transparent cover and a domed divergent Fresnel lens.

5. The domed divergent Fresnel lens of claim 4, is covered on the top of the domed upper transparent cover of the CPC of claim 4.

6. The inflatable non-imaging non-tracking solar concentrator of claim 3, is filled with helium or hydrogen.

7. The concentrating receiver of claim 3, comprises a concentrating photovoltaic panel and a heat exchanger.

8. The airship comprising a body with a transparent upper cover of claim 1, comprises a hull configured to contain the inflatable non-imaging non-tracking solar concentrator of claim 6 as lighter than air gas containers to generate lifting force.
